(19) United States
(12) Patent Application Publication
(10) Pub. No.: US 2026/0238116 A1
(43) Pub. Date: Aug. 13, 2026

(54) SWITCHING CONTROL CIRCUIT, INTEGRATED CIRCUIT, AND POWER SUPPLY CIRCUIT

(71) Applicant: FUJI ELECTRIC CO., LTD., Kawasaki-shi (JP)

(72) Inventor: Ryuji YAMADA, Tokyo (JP)

(73) Assignee: FUJI ELECTRIC CO., LTD., Kawasaki-shi (JP)

(21) Appl. No.: 19/432,787

(22) Filed: Dec. 24, 2025

(30) Foreign Application Priority Data
Feb. 13, 2025 (JP) 2025-021480

(51) Int. Cl. H02M 1/088; G01R 19/165; H02M 1/00; H02M 1/42; H02M 7/217; H03K 17/0812; H03K 17/13; H03K 17/081

(52) U.S. Cl. CPC H02M 1/088; G01R 19/16571; G01R 19/16576; H02M 1/0009; H02M 1/0019; H02M 1/4225; H02M 7/217; H03K 17/08122; H03K 17/133; H03K 17/08104

(57) ABSTRACT

A switching control circuit for a power supply circuit that generates an output voltage from an AC voltage. The power supply circuit includes an output capacitor, an inductor receiving a rectified voltage corresponding to the AC voltage, a first transistor connected to the inductor at a connection node and controlling an inductor current, a second transistor located between the inductor and the output capacitor, and a first resistor between the output capacitor and the connection node, for detecting a first current flowing through the second transistor. The switching control circuit complementarily switches the first and second transistors, and includes: a detection circuit detecting a voltage across the first resistor; a first driver circuit driving the first transistor based on the output voltage and a detection result of the detection circuit; and a second driver circuit driving the second transistor to be turned on and off complementarily to the first transistor.

### CROSS-REFERENCE TO RELATED APPLICATION

This application claims priority pursuant to 35 U.S.C. §119 from Japanese Patent Application No. 2025-021480, filed on February 13, 2025, of which is incorporated herein by reference.

### BACKGROUND

### Technical Field

The present invention relates to a switching control circuit, an integrated circuit, and a power supply circuit.

### Related Art

Power factor correction circuits include a circuit that operates in a critical mode, in which a transistor is turned on when an inductor current reaches a predetermined value (for example, zero). Further, in some cases, a transformer including a primary coil and a secondary coil is used to detect whether the inductor current flowing through the primary coil has reached the predetermined value, based on a voltage of the secondary coil (for example, Japanese Patent Application Publication No. 2021-044969, Japanese Patent No. 7501267, Japanese Patent Application Publication No. 2022-041912, Japanese Patent Application Publication No. 2008-211881, and "IR2111(S)&(PbF)", [online], April 12, 2004, International Rectifier, [retrieved on January 28, 2025], Internet <URL: https://www.infineon.com/dgdl/Infineon-IR2111-DS-v01_00-EN.pdf?fileId=5546d462533600a4015355c810e51682>).

However, it may be difficult to detect that the inductor current flowing through the primary coil has reached the predetermined value based on the voltage of the secondary coil.

### SUMMARY

An aspect of the present disclosure is a switching control circuit for a power supply circuit that generates an output voltage of a target level, at an output capacitor, from an alternating current (AC) voltage inputted to the power supply circuit, the power supply circuit including the output capacitor, an inductor configured to receive a rectified voltage corresponding to the AC voltage, a first transistor connected to the inductor at a connection node and configured to control an inductor current flowing through the inductor, a second transistor located between the inductor and the output capacitor, and a first resistor located between the output capacitor and the connection node of the inductor and the first transistor, the first resistor being configured to detect a first current flowing through the second transistor, the switching control circuit being configured to complementarily switch the first transistor and the second transistor in the power supply circuit, the switching control circuit comprising: a detection circuit configured to detect a voltage generated across the first resistor; a first driver circuit configured to drive the first transistor based on the output voltage and a result of a detection of the detection circuit; and a second driver circuit configured to drive the second transistor so as to be turned on and off complementarily to the first transistor.

An aspect of the present disclosure is a power supply circuit configured to generate an output voltage of a target level from an alternating current (AC) voltage inputted thereto, the power supply circuit comprising: an output capacitor at which the output voltage is generated; n inductors configured to each receive a rectified voltage corresponding to the AC voltage, n being an integer of 2 or more, the n inductors having n inductor currents respectively flowing therethrough; n first transistors configured to respectively control the n inductor currents, and being respectively connected to the n inductors through n connection nodes; n second transistors located respectively between the n inductors and the output capacitor; n first resistors located respectively between the output capacitor and the n connection nodes, the n first resistors being configured to detect n first currents respectively flowing through the n second transistors; and n switching control circuits configured to complementarily switch the n first transistors and the n second transistors, each of the n switching control circuits including: a detection circuit configured to detect a voltage generated across one of the n first resistors corresponding to said each switching control circuit, a first driver circuit configured to drive one of the n first transistors corresponding to said each switching control circuit, based on the output voltage and a result of the detection of the detection circuit, and a second driver circuit configured to drive one of the n second transistors corresponding to said each switching control circuit, so as to be respectively turned on and off complementarily to the one first transistors corresponding to said each switching control circuit, and the n switching control circuits being configured to switch the n first transistors to perform an interleaving operation.

### BRIEF DESCRIPTION OF THE DRAWINGS

FIG. 1 is a diagram illustrating an example of a boost chopper part of an AC-DC converter 1.

FIG. 2 is a diagram illustrating an example of a voltage Vds and an inductor current IL in the AC-DC converter 1.

FIG. 3 is a diagram illustrating an example configuration of the AC-DC converter 10.

FIG. 4 is a diagram illustrating an example configuration of a power factor correction IC 24.

FIG. 5 is a diagram illustrating an example configuration of a power factor correction IC 24a.

FIG. 6 is a diagram illustrating an example configuration of a power factor correction IC 24b.

FIG. 7 is a diagram illustrating an example configuration of an AC-DC converter 12.

FIG. 8 is a diagram illustrating an example configuration of a general AC-DC converter 500.

### DETAILED DESCRIPTION

At least the following matters will be apparent from description of the present specification and the attached drawings. Hereinafter, identical or equivalent components, members, and the like illustrated in the drawings are denoted by the same reference numerals, and a repeated description thereof may be omitted as appropriate.

### Case Where Inductor Current IL is Detected by Using Secondary Coil

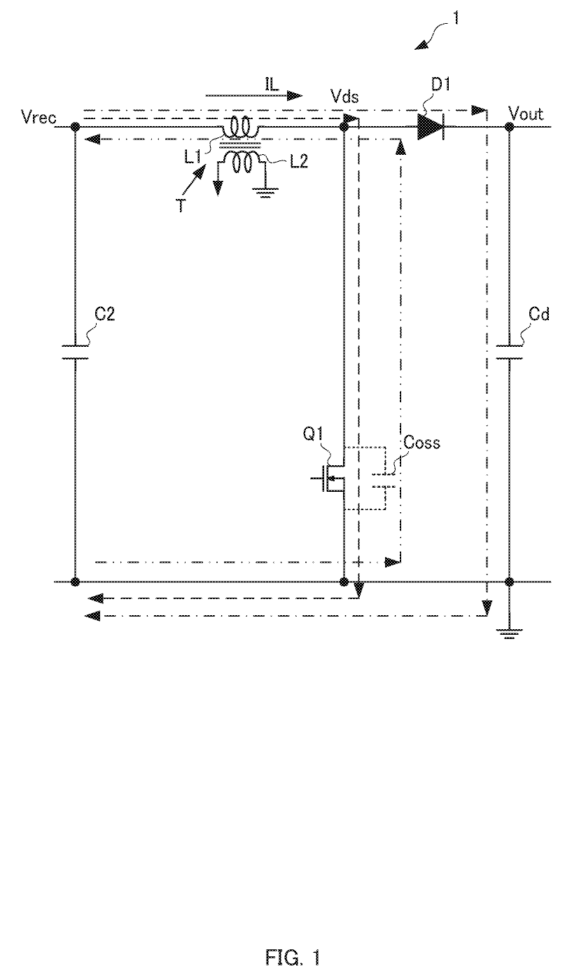

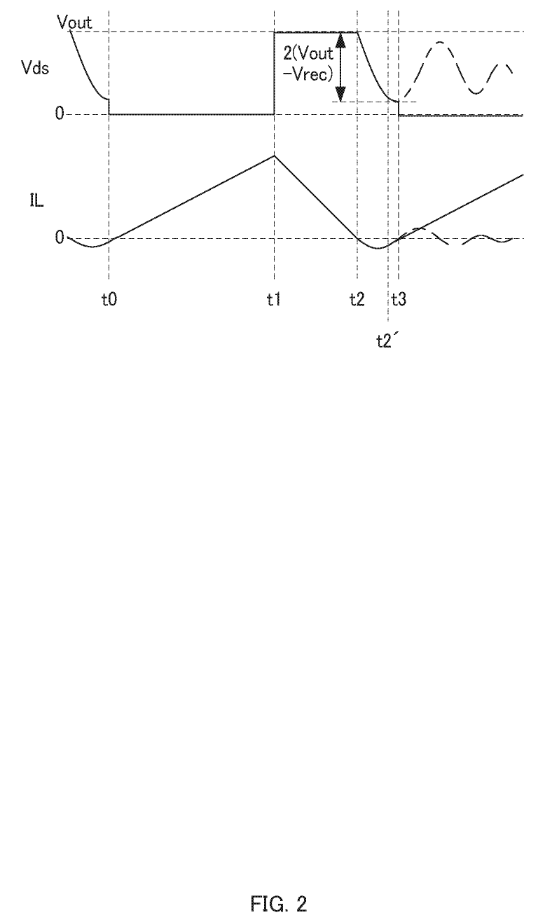

FIG. 1 is a diagram illustrating an example of a boost chopper part of an AC-DC converter 1, and FIG. 2 is a diagram illustrating an example of a voltage Vds and an inductor current IL in the AC-DC converter 1. Note that the AC-DC converter 1 is assumed to be a power factor correction circuit that operates in a "critical mode". Here, the "critical mode" is a mode in which the switching is set to on after the inductor current IL reaches zero.

The boost chopper includes an NMOS transistor Q1, a diode D1, and a primary coil L1 of a transformer T that includes the primary coil L1 and a secondary coil L2. Further, the secondary coil L2 is provided to detect that the inductor current IL flowing through the primary coil L1 has reached a predetermined value (for example, zero amperes).

Hereinafter, a route through which the inductor current IL flows is described with reference to FIG. 2. First, when the NMOS transistor Q1 turns on at time t0 of FIG. 2, the inductor current IL flows to the ground via the primary coil L1 and the NMOS transistor Q1 as illustrated by the dashed lines in FIG. 1. In this case, a voltage Vds between the drain and the source of the NMOS transistor Q1 reaches a ground voltage.

Next, when the NMOS transistor Q1 turns off at time t1, the inductor current IL flows through a capacitor Cd via the diode D1, as illustrated by the dashed-dotted lines in FIG. 1, and gradually decreases. In this case, since the diode D1 turns on, the voltage Vds reaches an output voltage Vout. Then, a parasitic capacitance Coss of the NMOS transistor Q1 is charged at the output voltage Vout.

Then, the diode D1 turns off at time t2 at which the inductor current IL reaches the predetermined value. When the diode D1 turns off, the voltage Vds is not maintained at the output voltage Vout. Further, the voltage Vds (that is, output voltage Vout) maintained in the parasitic capacitance Coss is higher than a rectified voltage Vrec. Accordingly, as illustrated by dashed-two-dotted lines of FIG. 1, the parasitic capacitance Coss and the primary coil L1 starts a resonance operation, and the inductor current IL flows from the parasitic capacitance Coss to the input side via the primary coil L1. Since the parasitic capacitance Coss is discharged in this case, the voltage Vds drops.

Thereafter, at time t3, when the parasitic capacitance Coss is discharged to a certain level (for example, the voltage Vds drops from the output voltage Vout by 2×(Vout-Vrec)), the inductor current IL reaches the predetermined value again, and the NMOS transistor Q1 turns on again in this case. Hereinafter, similar operations are repeated.

Further, the secondary coil L2 detects time (for example, time t2') at which the voltage level of the voltage Vds falls below a voltage level of the output voltage Vout to detect that the inductor current IL reaches the predetermined value.

However, the rectified voltage Vrec greatly varies depending on an input phase, and a variation width (that is 2×(Vout-Vrec)) of the voltage Vds described above also varies depending on the variation of the rectified voltage Vrec. Accordingly, accurate determination that the inductor current IL reaches the predetermined value through comparison with a certain voltage level is difficult to achieve only by adjusting setting values of the transformer T and the AC-DC converter 1.

Thus, in the present embodiment below, an AC-DC converter 10 is described capable of detecting that the inductor current IL has reached the predetermined value, without using the transformer T (that is the secondary coil L2).

### Present Embodiment

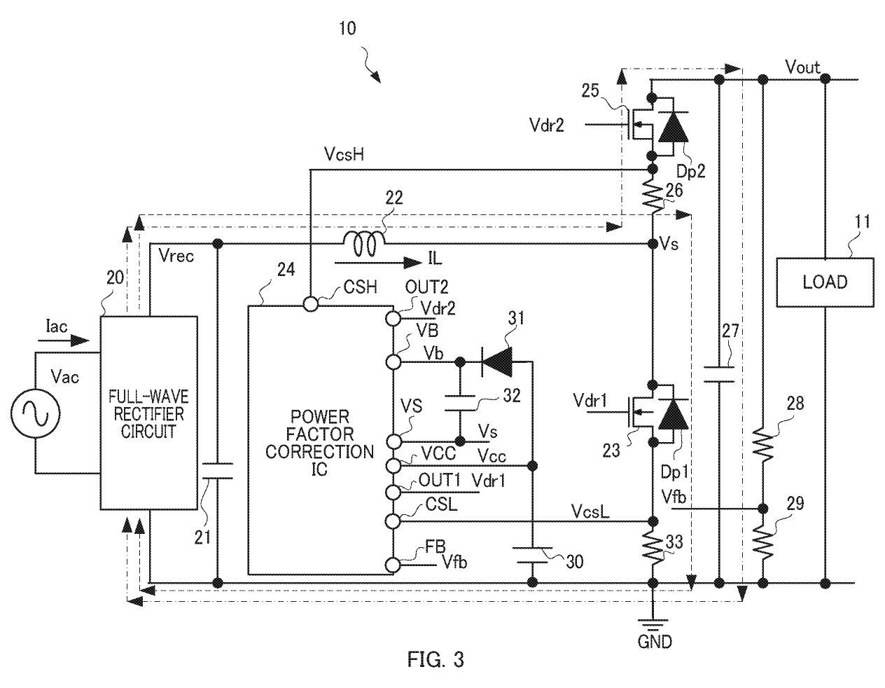

FIG. 3 is a diagram illustrating an example configuration of the AC-DC converter 10 that is an embodiment of the present invention. The AC-DC converter 10 is a boost chopper type power supply circuit that generates an output voltage Vout of a target level from an AC voltage Vac of a commercial electric source. The AC-DC converter 10 applies the output voltage Vout to a load 11 to supply electric power to the load 11. Further, as described in detail later, the AC-DC converter 10 includes an NMOS transistor 23 (described later) and an NMOS transistor 25 for synchronous rectification, and operates as a power factor correction circuit in the critical mode.

Note that, as described in detail later, the dashed lines in FIG. 3 illustrate the route of the inductor current IL when the NMOS transistor 23 is on (that is, the NMOS transistor 25 is off), and the dashed-dotted lines illustrate the route of the inductor current IL when the NMOS transistor 23 is off (that is, the NMOS transistor 25 is on).

The AC-DC converter 10 includes a full-wave rectifier circuit 20, capacitors 21, 27, and 32, an inductor 22, the NMOS transistors 23 and 25, a power factor correction IC 24, resistors 26, 28, 29, and 33, a power supply 30, and a diode 31.

The full-wave rectifier circuit 20 full-wave rectifies the inputted predetermined AC voltage Vac, and applies the rectified voltage to the capacitor 21 and the inductor 22 as an input voltage Vrec. The AC voltage Vac is a voltage whose effective value is 140 to 240 V and whose frequency is 50 to 60 Hz. In the following description, in the present embodiment, voltages are basically potential differences with respect to a reference point (GND in FIG. 3). However, the AC voltage Vac indicates a voltage between terminals. Further, a current from the commercial power source is referred to as input current Iac.

The capacitor 21 smooths the input voltage Vrec, and the capacitor 27 configures a boost chopper circuit together with the inductor 22 and the NMOS transistors 23 and 25. Accordingly, a charging voltage of the capacitor 27 is the DC output voltage Vout. The capacitor 27 corresponds to "output capacitor".

The case where the inductor current IL flows in the direction of the arrows illustrated in FIG. 3 is referred to as that the inductor current IL flows in a positive direction, and a case where the inductor current IL flows in the direction opposite to the arrows is referred to as that the inductor current IL flows in a negative direction.

The NMOS transistor 23 is a switching device for controlling the inductor current IL flowing through the inductor 22 and for controlling power to the load 11 of the AC-DC converter 10. Note that, although the NMOS transistor 23 is an n-type metal oxide semiconductor (MOS) transistor in the present embodiment, the transistor 23 may be, for example, a bipolar transistor, an IGBT, or the like.

Further, a gate electrode of the NMOS transistor 23 is coupled to a terminal OUT1 of the power factor correction IC 24. The NMOS transistor 23 includes a parasitic diode Dp1. When a bipolar transistor is used instead of the NMOS transistor 23, a diode corresponding to the parasitic diode Dp1 is provided in parallel to the bipolar transistor. The NMOS transistor 23 corresponds to "first transistor".

The power factor correction IC 24 is an integrated circuit that complementarily switches the NMOS transistor 23 and the NMOS transistor 25 for synchronous rectification such that the level of the output voltage Vout reaches the target level (for example, 400 V), while correcting the power factor of the AC-DC converter 10. Specifically, the power factor correction IC 24 drives the NMOS transistor 23 based on the inductor current IL and the output voltage Vout. As details of the power factor correction IC 24 are described later, the power factor correction IC 24 is provided with terminals CSH, CSL, FB, OUT1, OUT2, VB, VCC, and VS. In the present embodiment, terminals of the power factor correction IC 24 other than the terminals CSH and the like are omitted for convenience. Note that the power factor correction IC 24 corresponds to "switching control circuit".

The NMOS transistor 25, located between the inductor 22 and the capacitor 27, is a transistor for synchronous rectification and is switched on and off complementarily to the NMOS transistor 23. Further, a gate electrode of the NMOS transistor 25 is coupled to the terminal OUT2 of the power factor correction IC 24. As described in detail later, when the NMOS transistor 23 is turned off, the NMOS transistor 25 is turned on to cause the inductor current IL to flow from the inductor 22 to the capacitor 27. Further, the NMOS transistor 25 includes a parasitic diode Dp2. The NMOS transistor 25 corresponds to "second transistor".

The resistor 26 is located between a source electrode of the NMOS transistor 25 and a connection node of the inductor 22 and the NMOS transistor 23. Further, the resistor 26 detects the inductor current IL flowing through the NMOS transistor 25. Furthermore, a voltage VcsH generated across the resistor 26 is applied to the terminal CSH of the power factor correction IC 24. The current flowing through the NMOS transistor 25 corresponds to "first current", and the resistor 26 corresponds to "first resistor".

Further, although the resistor 26 is located between the source electrode of the NMOS transistor 25 and the connection node of the inductor 22 and the NMOS transistor 23 in the present embodiment, the resistor 26 may be located between a drain electrode of the NMOS transistor 25 and a high-potential side of the capacitor 27.

The resistor 26 may be used to detect a flow of overcurrent in the NMOS transistor 25, in addition to the detection of the inductor current IL flowing through the NMOS transistor 25. The resistor 26 may also be used for other protecting operations.

Further, in a case where the resistor 26 is used for detecting overcurrent and the protecting operations, a transmission circuit 104 described later may turn on and off the NMOS transistor 23 based on a voltage generated across the resistor 26.

The resistors 28 and 29 configure a voltage divider circuit that divides the output voltage Vout, and generates a feedback voltage Vfb used to switch the NMOS transistor 23. The feedback voltage Vfb, generated across a node to which the resistors 28 and 29 are coupled, is applied to the terminal FB.

The power supply 30 configures a bootstrap circuit together with the diode 31 and the capacitor 32, and supplies a power supply voltage Vb to the terminal VB of the power factor correction IC 24. Further, the power supply 30 supplies a power supply voltage Vcc to the terminal VCC of the power factor correction IC 24.

The diode 31 includes an anode coupled to the power supply 30 and a cathode coupled to the capacitor 32, and charges the capacitor 32 at the power supply voltage Vcc in a time period in which the NMOS transistor 23 is on and a voltage Vs of the connection node of the inductor 22 and the NMOS transistor 23 is the ground voltage. Further, the voltage Vs is applied to the terminal VS of the power factor correction IC 24.

The capacitor 32 is charged by a current from the diode 31, and the power supply voltage Vb is applied to the capacitor 32, with reference to the voltage Vs. The capacitor 32 supplies the power supply voltage Vb to the terminal VB of the power factor correction IC 24.

The resistor 33 is located between the NMOS transistor 23 and the ground to detect a current flowing through the NMOS transistor 23. Further, a voltage VcsL generated across the resistor 33 is applied to the terminal CSL of the power factor correction IC 24. The current flowing through the NMOS transistor 23 corresponds to "second current", and the resistor 33 corresponds to "second resistor".

The resistor 33 may be used to detect a flow of overcurrent in the NMOS transistor 23, in addition to the detection the inductor current IL flowing through the NMOS transistor 23. Further, the resistor 33 may be used for other protecting operations. When the resistor 33 is used for detecting overcurrent and the protecting operations, a control circuit 103 described later may turn on and off the NMOS transistor 23 based on the voltage generated across the resistor 33.

### Configuration of Power Factor Correction IC 24

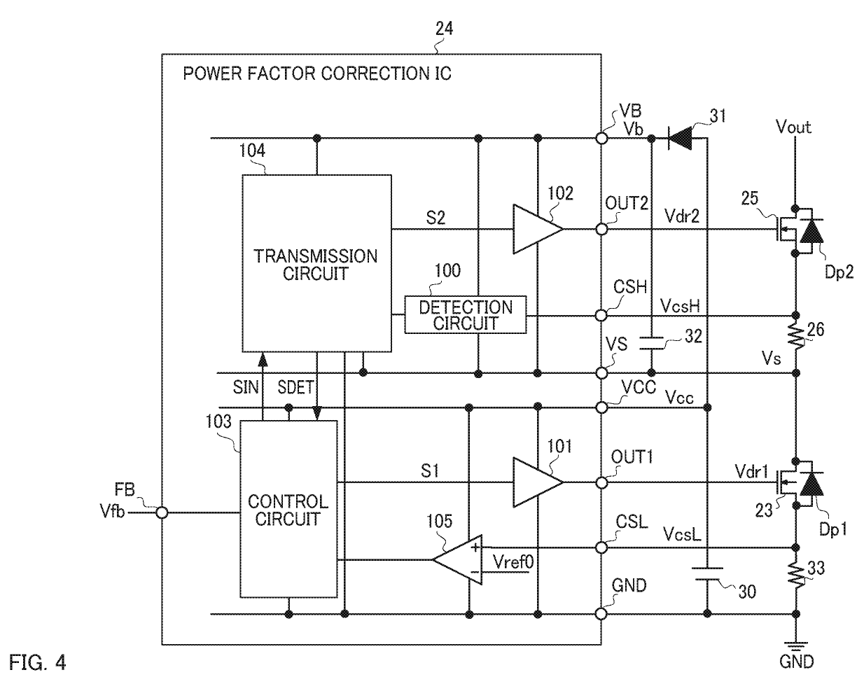

FIG. 4 is a diagram illustrating an example configuration of the power factor correction IC 24. The power factor correction IC 24 complementarily switches the NMOS transistors 23 and 25. The power factor correction IC 24 includes a detection circuit 100, driver circuits 101 and 102, the control circuit 103, the transmission circuit 104, and a comparator 105.

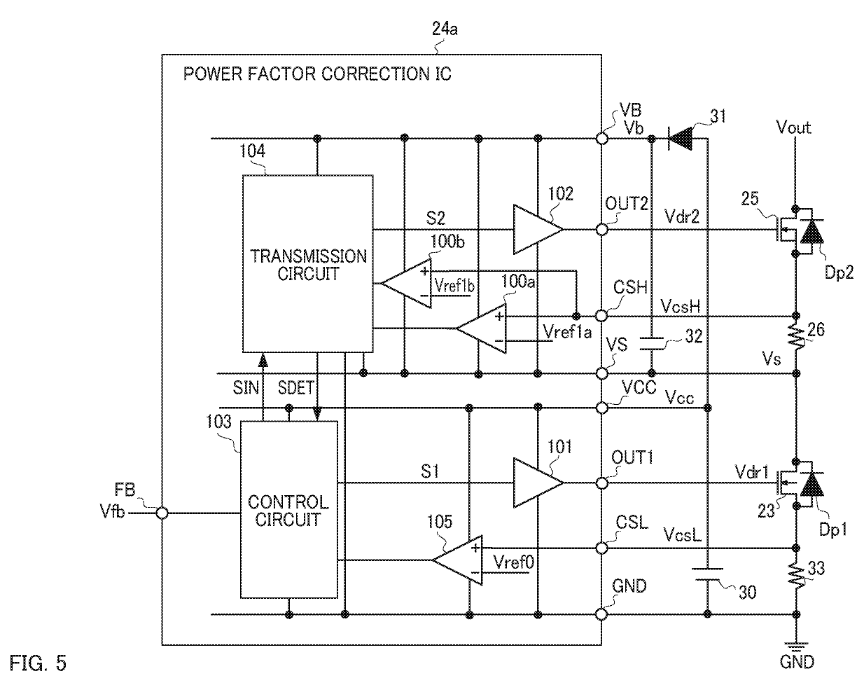

The detection circuit 100 detects the voltage generated across the resistor 26 and detects that the inductor current IL has reached the predetermined value (for example, zero amperes), based on the voltage generated across the resistor 26. Specifically, as illustrated in FIG. 5, the detection circuit 100 may be a comparator 100a that compares the voltage generated across the resistor 26 with a reference voltage Vref1a indicating that the inductor current IL flowing through the NMOS transistor 25 is the predetermined value.

In a case of using the comparator 100a, in order to determine whether the inductor current IL is an overcurrent, a comparator 100b is provided which compares the voltage generated across the resistor 26 with a reference voltage Vref1b indicating that the inductor current is the overcurrent. The reference voltages Vref1a and Vref1b are reference voltages different from each other.

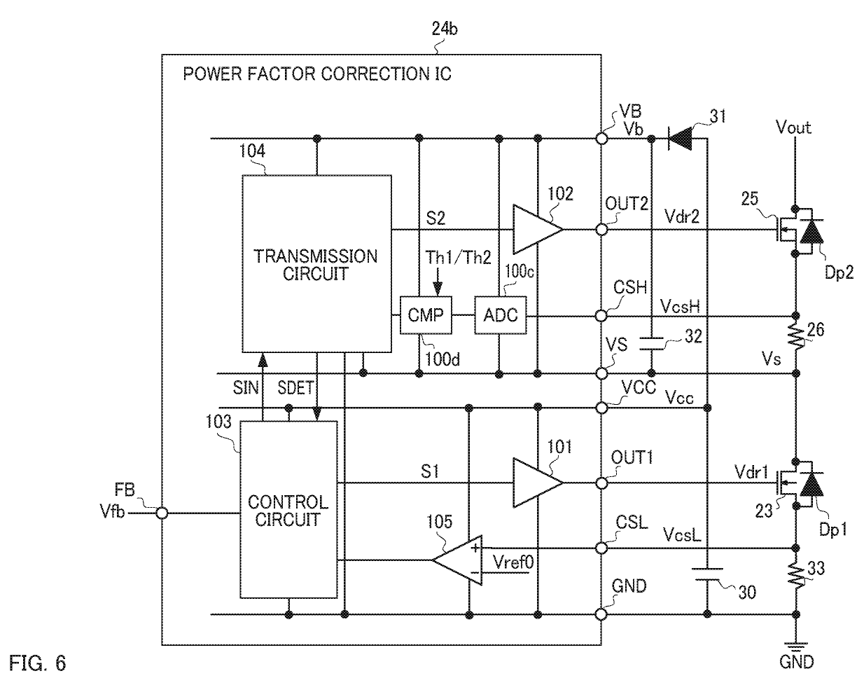

Further, as illustrated in FIG. 6, the detection circuit 100 may include an analog-to-digital converter circuit (ADC) 100c that converts the voltage generated across the resistor 26 to a digital value and a digital comparator (CMP) 100d. In this case, the transmission circuit 104 described later may transmit a signal (for example, signal SDET) to a circuit (for example, the control circuit 103 described later) that operates at the power supply voltage Vcc based on a result of the comparison of the comparator 100d.

On the other hand, the transmission circuit 104 described later may transmit the digital value to the control circuit 103 described later, and the control circuit 103 may include the digital comparator 100d that compares the digital value with a threshold. Then, the control circuit 103 may output a signal (for example, a signal S1) to a circuit (for example, the driver circuit 101 described later) that operates at the power supply voltage Vcc based on the result of the comparison of the comparator 100d.

Further, the comparator 100d compares the digital value with a first threshold Th1 for detecting that the inductor current IL has reached the predetermined value and a second threshold Th2 for detecting that the inductor current IL has become the overcurrent. The first threshold Th1 and the second threshold Th2 are thresholds different from each other. Further, although one comparator 100d compares the digital value with the first threshold Th1 and with the second threshold Th2, two comparators may compare the digital value with the first threshold Th1and the second threshold Th2, respectively.

The driver circuit 101 drives the drives the NMOS transistor 23 based on the output voltage Vout and a result of the detection of the detection circuit 100. The driver circuit 101 corresponds to "first driver circuit".

The driver circuit 101 switches the NMOS transistor 23 based on the signal S1 from the control circuit 103 described later. Specifically, the driver circuit 101 turns on and off the NMOS transistor 23 based on the output voltage Vout, the result of the detection of the detection circuit 100, and a result of the detection of the comparator 105 described later. Specifically, when the detection circuit 100 detects that the inductor current IL has reached the predetermined value, the driver circuit 101 turns on the NMOS transistor 23. When a time period corresponding to the output voltage Vout elapses, the driver circuit 101 turns off the NMOS transistor 23.

The driver circuit 102 drives the NMOS transistor 25 such that the NMOS transistor 25 is turned on and off complementarily to the NMOS transistor 23. The driver circuit 102 switches the NMOS transistor 25 based on a signal S2 from the transmission circuit 104 described later. The driver circuit 102 corresponds to "second driver circuit".

The control circuit 103 outputs the signal S1 for controlling the NMOS transistor 23, based on the signal SDET from the transmission circuit 104 described later, the output voltage Vout, and a result of the comparison of the comparator 105 described later. Further, the control circuit 103 outputs a signal SIN for controlling the NMOS transistor 25 to the transmission circuit 104 described later.

Further, when the comparator 105 described later detects that the inductor current IL flowing through the NMOS transistor 23 is overcurrent, the control circuit 103 outputs the signal S1 that turns off the NMOS transistor 23 to the driver circuit 101. The signal S1 corresponds to "first signal", and the signal SIN corresponds to the second signal.

The transmission circuit 104 transmits the signal SIN to the driver circuit 102 and switches the NMOS transistor 25 via the driver circuit 102. Specifically, the transmission circuit 104 transmits the result of the detection of the detection circuit 100 to the control circuit 103 and transmits the signal S2 to the driver circuit 102 based on the signal SIN. Further, in a case where the detection circuit 100 includes the comparator 100a, the transmission circuit 104 transmits a result of the comparison of the comparator 100a to the control circuit 103.

Then, the driver circuit 101 drives the NMOS transistor 23 based on the signal S1. Further, the driver circuit 102 drives the NMOS transistor 25 based on the signal SIN.

Further, the transmission circuit 104 provides an interface between a circuit that operates at the power supply voltage Vb (for example, the detection circuit 100) and a circuit that operates at the power supply voltage Vcc (for example, the control circuit 103) inside the power factor correction IC 24. In this case, the transmission circuit 104 shifts a level of a pulse signal based on a result of the detection of a voltage level of the power supply voltage Vb in the detection circuit 100, to a voltage level of the power supply voltage Vcc. Further, for example, an analog quantity or the like proportional to the current value of the inductor current IL does not have to be transmitted to indicate a timing at which the inductor current IL has reached the predetermined value, and the timing can be sufficiently indicated by the pulse signal.

The detection circuit 100, the driver circuit 102, and the transmission circuit 104 operate at the power supply voltage Vb. Further, the detection circuit 100 and the driver circuit 102 operate with reference to the voltage Vs.

The comparator 105 detects the inductor current IL flowing through the NMOS transistor 23 based on the voltage generated across the resistor 33. Specifically, when the voltage generated across the resistor 33 exceeds a reference voltage Vref0 indicating the overcurrent, the comparator 105 detects that the inductor current IL flowing through the NMOS transistor 23 is the overcurrent. The comparator 105 corresponds to "first comparator".

### Route of Inductor Current IL

Returning to FIG. 3, a route of the inductor current IL is described in the case where the NMOS transistors 23 and 25 are turned on and off. The dashed lines in FIG. 3 illustrate the route of the inductor current IL in the case where the NMOS transistor 23 is on (that is the NMOS transistor 25 is off), and the dashed-dotted lines illustrate the route of the inductor current IL in the case where the NMOS transistor 23 is off (that is the NMOS transistor 25 is on).

First, in the case where the NMOS transistor 23 is on, the inductor current IL flows through in the order of the full-wave rectifier circuit 20, the inductor 22, the NMOS transistor 23, and the resistor 33. Accordingly, the resistor 33 can detect the inductor current IL flowing through the NMOS transistor 23.

Next, in the case where the NMOS transistor 23 is off, the inductor current IL flows through in the order of the full-wave rectifier circuit 20, the inductor 22, the resistor 26, the NMOS transistor 25, and the capacitor 27. Accordingly, the resistor 26 can detect the inductor current IL flowing through the NMOS transistor 25.

Further, in the case where the NMOS transistor 23 is turned on and the NMOS transistor 23 is turned off, the inductor current IL reaches its peak, then decreases, and reaches the predetermined value. Thereafter, since the voltage level of the output voltage Vout is higher than a voltage level of the rectified voltage Vrec when the NMOS transistor 25 is on, the inductor current IL tends to flow in the negative direction. Accordingly, the detection of the inductor current IL reaching the predetermined value can be performed by detecting the voltage generated across the resistor 26.

A switching control circuit that can detect the timing at which the inductor current reaches the predetermined value without using the secondary coil can be thereby provided.

### Modified Example

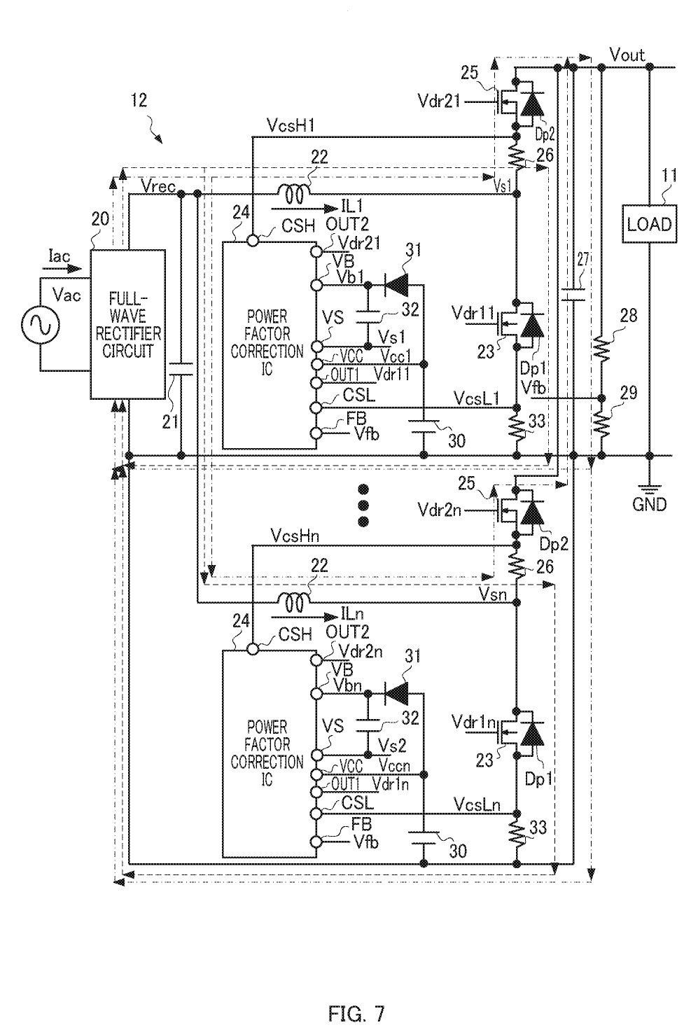

FIG. 7 is a diagram illustrating an example configuration of an AC-DC converter 12. FIG. 7 illustrates an example of the case where the AC-DC converter 12 has an interleaving configuration by using n (n is an integer of 2 or more) power factor correction ICs 24. Since the configuration of a circuit around the power factor correction ICs 24 is the same as that of the AC-DC converter 10 in FIG. 1, explanation thereof is omitted. Further, each of the n power factor correction ICs 24 switches a corresponding one of n NMOS transistors 23 corresponding to the respective n power factor correction ICs 24 such that an interleaving operation is performed. Further, each of the n power factor correction ICs 24 drives a corresponding one of n NMOS transistors 25 corresponding to the respective n power factor correction ICs 24.

### Route of Inductor Current IL in Case of Interleaving Configuration

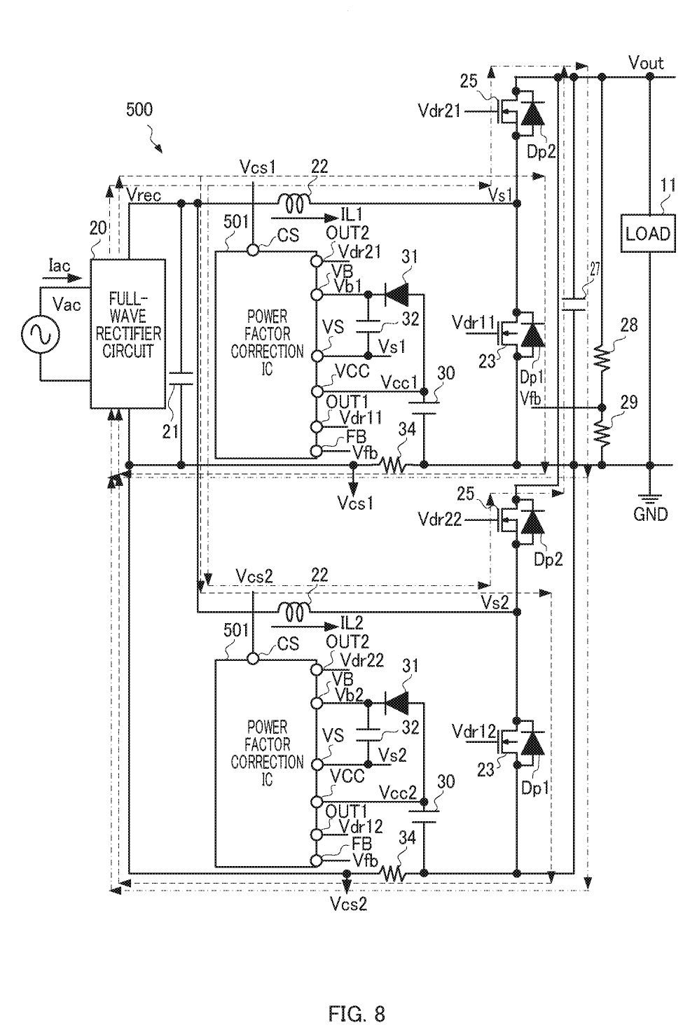

The route is explained with reference to FIG. 7 of the inductor current IL in the case where the NMOS transistors 23 and 25 are turned on and off. First, explanation is given to a route of each of inductor currents IL1 and IL2 in the case where the NMOS transistors 23 and 25 are turned on and off in a general AC-DC converter 500 illustrated in FIG. 8. Note that FIG. 8 is a diagram illustrating an interleaving configuration in the case where n is 2.

In FIG. 8, each of the power factor correction ICs 501 is provided with a resistor 34 to detect that a corresponding one of the inductor currents IL1 and IL2 reaches the predetermined value.

The dashed lines illustrated in FIG. 8 illustrate the routes of the inductor currents IL in the case where the NMOS transistor 23 is on (that is the NMOS transistor 25 is off), and the dashed-dotted lines illustrate the routes of the inductor currents IL in the case where the NMOS transistor 23 is off (that is the NMOS transistor 25 is on). The same applies to FIG. 7.

Since the routes of the inductor currents in the case where the NMOS transistors 23 are turned on or off are the same as the route explained with reference to FIG. 3, explanation thereof is omitted. Further, for example, in a time period in which the first NMOS transistor 23 and the second NMOS transistor 23 illustrated in FIG. 8 are off, a current obtained by adding up the currents IL1 and IL2 flowing through the inductors 22 flows to the ground via the capacitor 27. The current obtained by adding up the inductor currents IL1 and IL2 flowing toward the ground is divided due to a difference in impedances in the respective ground lines provided with the resistors 34.

Accordingly, in the case where the AC-DC converter 500 is configured to perform the interleaving operation, detection of each of the inductor currents IL1 and IL2 that reaches the predetermined value cannot be performed simply based on the currents flowing through the resistors 34.

Further, in each of the power factor correction ICs 501 of FIG. 8, since the NMOS transistor 25 is on when the NMOS transistor 23 is off, the voltage Vds illustrated in FIG. 2 does not decrease even when the inductor current IL decreases and reaches the predetermined value. Accordingly, the detection of the inductor current IL that reaches the predetermined value cannot be performed even if a secondary coil is provided in the inductor 22.

On the other hand, in the case where the resistors 26 are provided between, for example, the NMOS transistors 25 and the connection nodes of the inductor 22 and the NMOS transistor 23 as illustrated in FIG. 7, each of inductor currents IL1 to ILn can be detected before merging in the capacitor 27.

Accordingly, a switching control circuit that can detect the timings at which the inductor currents reach the predetermined value without using the secondary coils can be thereby provided also in a circuit configuration that performs the interleaving operation while performing synchronous rectification using the NMOS transistors 25.

### Overview

The AC-DC converter 10 of the present embodiment has been explained above. The power factor correction IC 24 includes the detection circuit 100 and the driver circuits 101 and 102. A switching control circuit that can detect the timing at which the inductor current reaches the predetermined value without using the secondary coil can be thereby provided.

Further, the resistor 26 is located between the NMOS transistor 25 and the connection node of the inductor 22 and the NMOS transistor 23. Since this configuration enables the detection of the voltage generated across the resistor 26 with reference to the voltage Vs, the detection that the inductor current IL reaches the predetermined value can be performed more accurately.

Further, the power factor correction IC 24 includes the control circuit 103 and the transmission circuit 104. A signal can be thereby transmitted between the circuit that operates at the power supply voltage Vb with reference to the voltage Vs (for example, the detection circuit 100) and the circuit that operates at the power supply voltage Vcc with reference to the ground (for example, the driver circuit 101).

Further, the detection circuit 100 is the comparator 100a. The detection that the inductor current IL reaches the predetermined value can be thereby performed in a simpler way than the case where the analog-to-digital converter circuit 100c is used. On the other hand, in the case where the analog-to-digital converter circuit 100c is provided, more sophisticated control such as, for example, suppression of input current distortion can also be performed by using information on the current value of the inductor current IL.

Further, the AC-DC converter 10 includes the resistor 33, and the power factor correction IC 24 includes the comparator 105. This configuration enables detection of whether the inductor current IL flowing through the NMOS transistor 23 is the overcurrent.

Further, the AC-DC converter 10 includes the diode 31 and the capacitor 32. The power supply voltage Vb can be thereby generated by utilizing the voltage level of the voltage Vs changing to the output voltage Vout and the ground.

Further, the AC-DC converter 12 performs the interleaving operation by using multiple power factor correction ICs 24. Further, using the resistors 26 enables independent detection of the inductor currents IL1 to ILn flowing through the respective NMOS transistors 25, and enables the detection of each of the inductor currents IL1 to ILn reaching the predetermined value, also in the case where the interleaving operation is performed.

Further, the AC-DC converter 12 includes the resistors 33, and the power factor correction ICs 24 includes the comparators 105. This configuration allows the detection of whether each of the inductor currents IL1 to ILn flowing through the respective NMOS transistors 23 is the overcurrent.

The present invention has been made in view of the conventional problems as described above, and an object of the present invention is to provide a switching control circuit that can detect the timing at which the inductor current reaches the predetermined value without using the secondary coil.

The present invention can provide a switching control circuit that can detect the timing at which the inductor current reaches the predetermined value without using the secondary coil.

Embodiment(s) of the present disclosure described above is/are simply to facilitate understanding of the present disclosure and is/are not in any way to be construed as limiting the present disclosure. The present disclosure may variously be changed or altered without departing from its essential features and encompass equivalents thereof.

What is claimed is:

1. A switching control circuit for a power supply circuit that generates an output voltage of a target level, at an output capacitor, from an alternating current (AC) voltage inputted to the power supply circuit, the power supply circuit including
the output capacitor,
an inductor configured to receive a rectified voltage corresponding to the AC voltage,
a first transistor connected to the inductor at a connection node and configured to control an inductor current flowing through the inductor,
a second transistor located between the inductor and the output capacitor, and
a first resistor located between the output capacitor and the connection node of the inductor and the first transistor, the first resistor being configured to detect a first current flowing through the second transistor,
the switching control circuit being configured to complementarily switch the first transistor and the second transistor in the power supply circuit, the switching control circuit comprising:
a detection circuit configured to detect a voltage generated across the first resistor;
a first driver circuit configured to drive the first transistor based on the output voltage and a result of a detection of the detection circuit; and
a second driver circuit configured to drive the second transistor so as to be turned on and off complementarily to the first transistor.

2. The switching control circuit according to claim 1, wherein
the first resistor is located between the second transistor and the connection node.

3. The switching control circuit according to claim 1, further comprising:
a control circuit configured to output a first signal for controlling the first transistor and a second signal to control the second transistor, based on the output voltage and the result of the detection of the detection circuit; and
a transmission circuit configured to transmit the result of the detection of the detection circuit to the control circuit and transmit the second signal to the second driver circuit, wherein
the first driver circuit drives the first transistor based on the first signal, and
the second driver circuit drives the second transistor based on the second signal.

4. The switching control circuit according to claim 3, wherein
the detection circuit is a comparator configured to compare the voltage generated across the first resistor with a reference voltage indicating that the first current is a predetermined value,
the transmission circuit transmits a result of the comparison of the comparator to the control circuit, and
the first driver circuit turns on the first transistor in response to a detection of the first current reaching the predetermined value, and turns off the first transistor in response to an elapse of a time period corresponding to the output voltage.

5. The switching control circuit according to claim 4, wherein the power supply circuit further includes
a capacitor configured to receive a voltage to operate the second driver circuit and the transmission circuit, and
a diode configured to charge the capacitor while the first transistor is on.

6. The switching control circuit according claim 1, wherein
the power supply circuit further includes a second resistor configured to detect a second current flowing through the first transistor,
the switching control circuit further includes a first comparator configured to detect the second current based on a voltage generated across the second resistor, and
the first driver circuit turns on and off the first transistor based on the result of the detection of the detection circuit, the output voltage, and a result of the detection of the first comparator.

7. A power supply circuit configured to generate an output voltage of a target level from an alternating current (AC) voltage inputted thereto, the power supply circuit comprising:
an output capacitor at which the output voltage is generated;
n inductors configured to each receive a rectified voltage corresponding to the AC voltage, n being an integer of 2 or more, the n inductors having n inductor currents respectively flowing therethrough;
n first transistors configured to respectively control the n inductor currents, and being respectively connected to the n inductors through n connection nodes;
n second transistors located respectively between the n inductors and the output capacitor;
n first resistors located respectively between the output capacitor and the n connection nodes, the n first resistors being configured to detect n first currents respectively flowing through the n second transistors; and
n switching control circuits configured to complementarily switch the n first transistors and the n second transistors,
each of the n switching control circuits including:
a detection circuit configured to detect a voltage generated across one of the n first resistors corresponding to said each switching control circuit,
a first driver circuit configured to drive one of the n first transistors corresponding to said each switching control circuit, based on the output voltage and a result of the detection of the detection circuit, and
a second driver circuit configured to drive one of the n second transistors corresponding to said each switching control circuit, so as to be respectively turned on and off complementarily to the one first transistors corresponding to said each switching control circuit, and
the n switching control circuits being configured to switch the n first transistors to perform an interleaving operation.

8. The power supply circuit according to claim 7, further comprising
n second resistors configured to detect n second currents respectively flowing through the n first transistors, wherein
each of the n switching control circuits includes a first comparator, the n first comparators being configured to detect the n second currents flowing through the n first transistors, based on n voltages generated across the n second resistors, respectively, and
the n first driver circuits turn on and off the n first transistors, based on the n results of the detection of the n detection circuits, the output voltage, and n results of the detection of the n first comparators, respectively.
